(19) United States
(12) Patent Application Publication
(10) Pub. No.: US 2006/0068593 A1
(43) Pub. Date: Mar. 30, 2006

(54) PATTERNING METHOD

(76) Inventors: Chang-Hu Tsai, Tainan City (TW); Prudence Wu, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/711,678

(22) Filed: Sep. 30, 2004

(51) Int. Cl. H01L 21/4763

(52) U.S. Cl. 438/710

(57) ABSTRACT

A patterning method is provided. First, a substrate comprising a film formed thereon is provided. Then, a photoresist layer is formed over the film. Next, the photoresist layer is developed to form a patterned photoresist layer. Then, the film is etched using a dry etching method. In addition, the dry etching method is performed at a temperature range of about −50° C. to about 50° C. using the patterned photoresist layer as an etching mask.

### BACKGROUND OF THE INVENTION

1. Field of the Invention

The present invention is generally related to a patterning method. More particularly, the present invention relates to a low temperature etching process for reducing defects.

2. Description of Related Art

Typically, in a semiconductor manufacturing process, lithographic and etch process is performed for patterning a film by using, for example, the following steps. In general, a photoresist layer is formed over the film over a semiconductor substrate. Next, the photoresist layer is exposed using a mask to transfer a specific pattern on the mask onto the surface of the photoresist layer. After the photoresist layer is trimmed with respect to the specific pattern transferred, the remaining patterned photoresist layer is used as an etching mask layer for etching an underlying film. Finally, after etching the film using the patterned photoresist layer as an etching mask, the patterned photoresist layer is removed. Thus, the film is patterned using lithographic and etch process described above.

As the development of the semiconductor process advances, the line width of the semiconductor structure is being minimized rapidly to increase the integration of the semiconductor device. However, with the reduction of the line width, a variety of problems arise in a conventional lithographic and etch process. First, the process window of the conventional lithographic and etch process decreases with the reducing line width. Especially, in the conventional lithographic process, the process temperature range of the electrostatic chuck (ESC) (e.g., larger than about 70° C.) is applicable are patterned photoresist layer may collapse. In addition, if the thickness of the photoresist layer is being reduced due to the reduction in the line width, it is very difficult pattern the thin photoresist layer. For example, defects become more obvious due to the miniaturization of the size of the semiconductor devices. In addition, the fine-tuning of the process window will result into another kind of defect (for example, if the ESC temperature is reduced, condensed defect may result). Accordingly, a novel process with a wider thickness range tolerance of a photoresist layer used for patterning films for fabricating the semiconductor devices without the problems described above is highly desirable.

### SUMMARY OF THE INVENTION

Accordingly, the present invention is directed to a patterning method for reducing the defects.

In addition, the present invention is also directed to a patterning method for reducing the deviation of the line width.

Moreover, the present invention is directed to a patterning method for resolving the problems of the conventional pattering method, such as the collapse of the patterned photoresist layer used as an etching mask of the etch step is prevented. In addition, the process window of the patterning method of the present invention is broader than that of the conventional method.

In accordance with an embodiment of the present invention, first, a substrate comprising a film formed over the substrate is provided. Then, a photoresist layer is formed over the film. Next, the photoresist layer is exposed and developed to form a patterned photoresist layer. Then, the film is etched by using a dry etch method. In addition, the dry etch method is performed at a temperature range of about −50° C. to about 50° C. by using the patterned photoresist layer as an etching mask.

In one embodiment of the present invention, the temperature range is between about −30° C. and about 30° C.

In one embodiment of the present invention, the temperature range is controlled via a susceptor positioned below the substrate.

In one embodiment of the present invention, the dry etch method comprises an anisotropic plasma etch method. In addition, the anisotropic plasma etch method is performed by directing an ionized plasma via a field.

In one embodiment of the present invention, the ionized plasma is formed by ionizing a plasma source comprising at least one inert gas selected from a group consisting of helium (He), neon (Ne), argon (Ar), krypton (Kr) and xenon (Xe).

In one embodiment of the present invention, a flow rate of the ionized plasma is in a range of about 20 sccm to about 200 sccm.

In one embodiment of the present invention, the plasma source further comprises an external plasma source. In addition, the external plasma source comprises CF₄:CHF₃, CF₄:CH₂F₂, C₂F₆:CHF₃, or C₂F₆:CH₂F₂. In another embodiment of the present invention, a gas flow ratio of CF₄ to CHF₃ of the CF₄:CHF₃, a gas flow ratio of CF₄ to CH₂F₂ of the CF₄:CH₂F₂, a gas flow ratio of C₂F₆ to CHF₃ of the C₂F₆:CHF₃, or a gas flow ratio of C₂F₆ to CHF₃ of the C₂F₆:CHF₃ is larger than 1.

In one embodiment of the present invention, the field comprises an electric field or a magnetic field. In another embodiment of the present invention, a power applied at one electrode for generating the electric field is in a range of about 150 W to about 300 W.

In one embodiment of the present invention, a thickness of the patterned photoresist layer is in a range of about 200 nm to about 500 nm.

In one embodiment of the present invention, the photoresist layer comprises a positive photoresist layer or a negative photoresist layer.

In one embodiment of the present invention, the film comprises a single layer or multiple layers. In one embodiment of the present invention, the film comprises a dielectric layer, an inter-metal dielectric (IMD) layer, or an inter-layer dielectric (ILD) layer. In another embodiment of the present invention, the film comprises an oxide layer, a nitride layer, a poly-silicon layer or a single crystal silicon layer.

In one embodiment of the present invention, the patterning method is performed to form a trench structure, a contact structure or a via structure in a film. In another embodiment of the present invention, the trench structure comprises a shallow trench isolation (STI) structure.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are schematic cross-sectional views illustrating a process flow of a patterning process according to one embodiment of the present invention.

FIG. 2A and FIG. 2B are pictures illustrating defects generated in the patterning process.

### DESCRIPTION OF EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

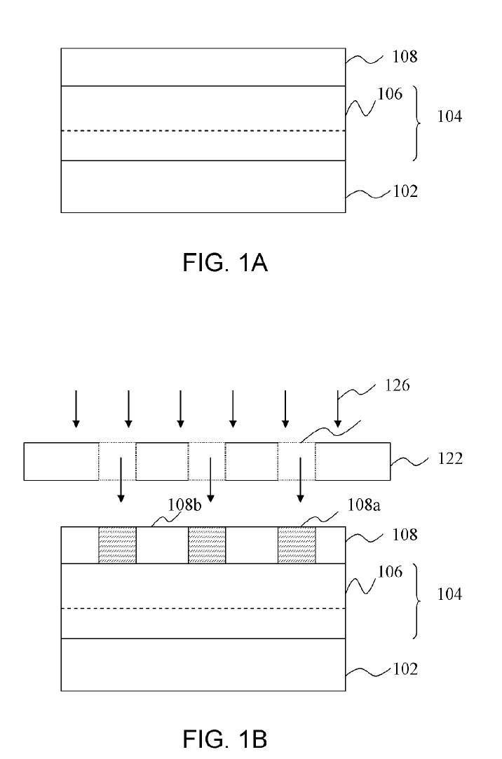

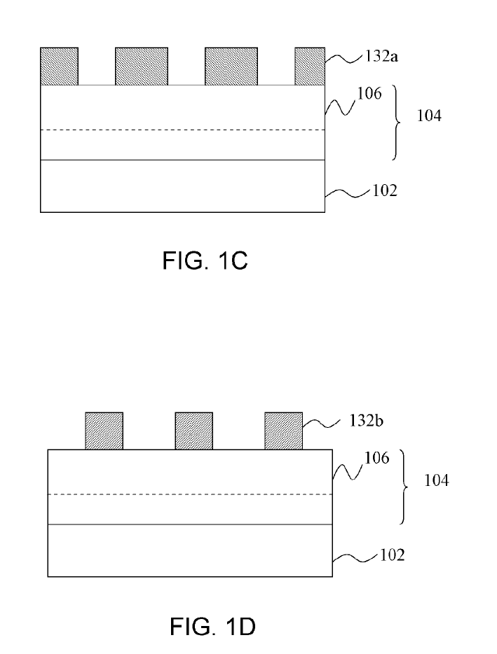

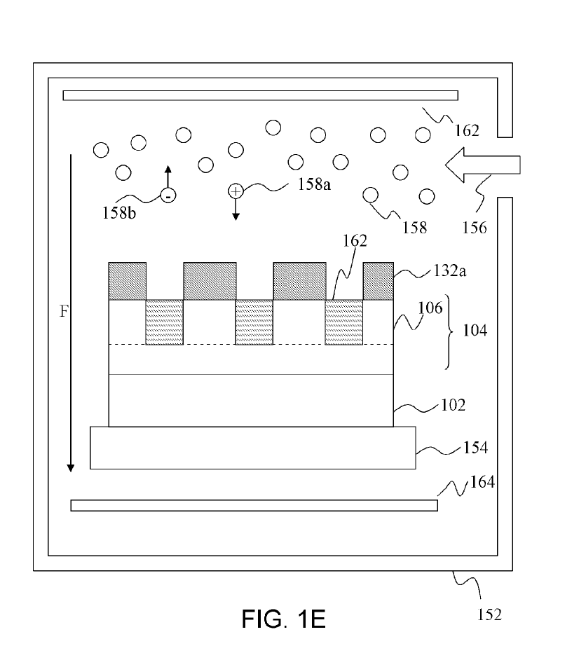

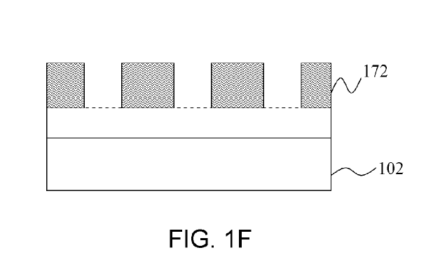

FIG. 1A to FIG. 1F are schematic cross-sectional views illustrating a process flow of a patterning process according to one embodiment of the present invention. Referring to FIG. 1A, a semiconductor structure 104 comprising, for example but not limited to, a film 106 is formed over, for example but not limited to, a substrate 102. Thereafter, a photoresist layer 108 is formed over the film 106 of the semiconductor structure 104.

Thereafter, referring to FIG. 1B, the photoresist layer 108 is exposed using a mask 122 having a predetermined pattern. The photoresist layer 108 is illuminated using a light 126 via the openings 124 of the mask 122. As shown in FIG. 1B, a portions of the photoresist layer 108 exposed by the light 126 are marked as regions 108a, and the unexposed regions are marked as regions 108b. In one embodiment of the present invention, the photoresist layer 108 comprises, for example but not limited to, a positive photoresist layer or a negative photoresist layer.

When the photoresist layer 108 is a positive photoresist layer, after the exposure and trimming process, the regions 108a are removed and the regions 108b remain over the film 106. Thus, a patterned photoresist layer 132a is formed over the film 106 as illustrated in FIG. 1C. Alternatively, when the photoresist layer 108 is a negative photoresist layer, after the exposure and trimming process, the regions 108b are removed and the regions 108a remain over the film 106. Thus, a patterned photoresist layer 132b is formed over the film 106 as illustrated in FIG. 1D. In one embodiment of the present invention, a thickness of the photoresist layer 132a or 132b is in a range of about 200 nm to about 500 nm, and preferably in a range of about 200 nm to about 350 nm.

Next, referring to FIG. 1E, a process chamber 152 is provided for etching step the film 106 using the patterned photoresist layer 132a or 132b. As shown in FIG. 1E, the film 106 formed over the substrate 102 is etched using the positive photoresist layer 123a illustrated in FIG. 1C as an etching mask in the process chamber 152. However, it should be noted that the film 106 may also be etched using a negative photoresist layer as illustrated in FIG. 1D as an etching mask. As shown in FIG. 1E, the substrate is chucked by a susceptor 154 comprising, for example but not limited to, an electrostatic chuck (ESC).

Referring to FIG. 1E, a dry etching process using, for example but not limited to, an ionized plasma 158. The ionized plasma 158 may be provided by, for example but not limited to, an ionized plasma source 156 filling the ionized plasma 158 into the chamber 152. It should be noted that a dry etching may be an isotropic or anisotropic. In the present embodiment of the present invention, the dry etching is anisotropic, wherein a field F comprising, for example, an electric field or a magnetic field, is adapted for controlling a direction of a flow of the ionized plasma 158. For example, in FIG. 1E, a downward electric field F is illustrated and generated by, for example but not limited to, a voltage difference between two electrodes 162 and 164. Therefore, positively charged ions of the ionized plasma 158 (e.g., positively charged plasma 158a) is directed and accelerated along the direction of the electric field F. Alternatively, negatively charged ions of the ionized plasma 158 (e.g., negatively charged plasma 158b) is directed and accelerated along the opposite direction of the electric field F. It is noted that, the direction of the electric field F illustrated in FIG. 1E is only provided as an example, and can not be used to limit the scope of the present invention.

Referring to FIG. 1E, the patterned photoresist layer 132a is provided as an etching mask. Therefore, only a region 162 of the film 106 exposed to the ionized plasma source 156 will be etched. Hereinafter, a variety of process parameters will be described. However, it should be noted that the process parameters is dependent on the actual environment of the process, and thus may be adjusted accordingly. In one embodiment of the present invention, a temperature of the dry etching process is in a range of, for example but not limited to, about −50° C. to about 50° C. In one embodiment of the present invention, the temperature range is between about −30° C. and about 30° C. The temperature may be applied through, for example but not limited to, the susceptor 154. In one embodiment of the present invention, a power applied at the electrode 164 may be, for example but not limited to, in a range of about 150 W to about 300 W.

According to an embodiment of the present invention, the ionized plasma source 156 is formed by, for example, ionizing a plasma source comprising at least one inert gas such as helium (He), neon (Ne), argon (Ar), krypton (Kr) and xenon (Xe). Moreover, a flow rate of the ionized plasma 158 may be, for example but not limited to, in a range of about 20 sccm to about 200 sccm.

According to another embodiment of the present invention, the plasma source further comprises, for example but not limited to, an external plasma source. For example, the external plasma source comprises a mixture of carbon fluorides comprises CF₄:CHF₃, CF₄:CH₂F₂, C₂F₆:CHF₃, or C₂F₆:CH₂F₂. In addition, a gas flow ratio of CF₄ to CHF₃ of the CF₄:CHF₃, a gas flow ratio of CF₄ to CH₂F₂ of the CF₄:CH₂F₂, a gas flow ratio of C₂F₆ to CHF₃ of the C₂F₆:CHF₃, or a gas flow ratio of C₂F₆ to CHF₃ of the C₂F₆:CHF₃ may be, for example but not limited to, larger than 1.

In one embodiment of the present invention, the film 106 may be a single layer or multiple layers. In addition, the film 106 comprises a dielectric layer, an inter-metal dielectric (IMD) layer, or an inter-layer dielectric (ILD) layer. Furthermore, the film 106 may be selected from a group consisting an oxide layer, a nitride layer, a poly-silicon layer and a single crystal silicon layer.

Thereafter, referring to FIG. 1F, after the film 106 is etched to form a patterned film 172. It is noted that the patterned film 172 has a similar or same pattern as the patterned photoresist layer 132a.

Referring to FIG. 1F, according to an embodiment of the present invention, the patterned film 172 may utilized to form, for example but not limited to, a trench structure, a contact structure or a via structure. For example, the trench structure may be a shallow trench isolation (STI) structure.

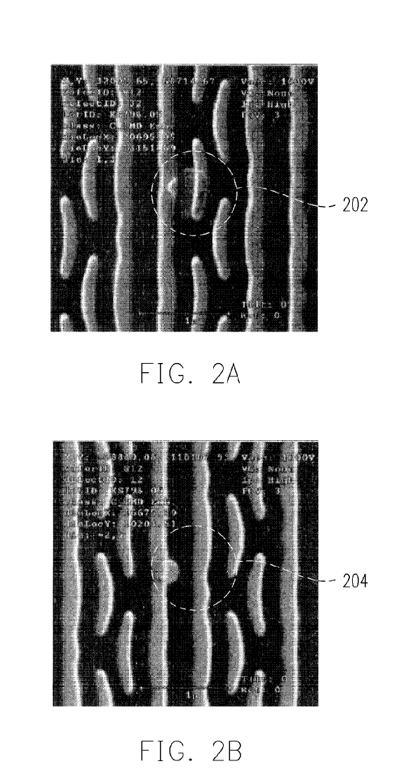

FIG. 2A and FIG. 2B are pictures illustrating defects generated in the patterning process. It is noted that, the defects 202 or 204 shown in FIG. 2A or 2B illustrate a kill defect (a defect may cause a failure of the operation of the semiconductor structure). The kill defect may be generated by, for example but not limited to, a condensation of a compound or a by-product produced by the reaction between the plasma and the material of the structure of the substrate. Hereinafter, Table 1 is listed for illustrating the defect count generated in the conventional patterning method and the patterning method of the present invention. In Table 1, the nodule defect presents a tiny defect having a size smaller than the line width of the structure, and may not be a kill defect. The other defect comprises, for example, fall-on defect (a defect due to the fall on particle from the environment), embedded particle (a particle generated from the prior process), or another kind of defect.

TABLE 1

| Count of | Total | | Nodule | Other |
|---|---|---|---|---|
| defect | count | Kill defect | defect | defect |
| Conventional | 410 | 41 | 320 | 49 |
| The | 49 | 8 | 39 | 2 |
| invention | | | | |

Furthermore, in one embodiment of the present invention, the external plasma source (e.g., a mixture of carbon fluorides) may be provided for reducing the deviation of the line width of the isolation region and that of the dense region. In the present invention, since the temperature is lower, and the field applied at the plasma is stronger, the deposition of the by-products of the plasma is unexpectedly increased, especially in the dense region. Therefore, by applying the external plasma source in the etching step, generation of the by-products of the plasma may be reduced, and thus the deviation of the line width of the isolation region and that of the dense region are minimized.

Accordingly, in the present invention, it is noted that the process temperature of the etching step is lower than that of the conventional etching step. In addition, a stronger field is provided for directing and accelerating the ionized plasma used in the etching step by, for example, applying a higher power to the electrode for producing the electric field. Therefore, collapsing of the patterned photoresist layer is effectively reduced. In addition, the defect count is also reduced. In addition, the deviation of the line width of the isolation region and that of the dense region are reduced by applying the external plasma source in the etch step.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A patterning method, comprising:
providing a substrate having a film formed over thereon;
forming a photoresist layer over the film;
exposing and developing the photoresist layer to form a patterned photoresist layer; and
etching the film using the patterned photoresist layer as an etching mask at a temperature range of about −50° C. to about 50° C.

2. The patterning method of claim 1, wherein the temperature range is between about −30° C. and about 30° C.

3. The patterning method of claim 1, wherein the temperature range is controlled via a susceptor positioned below the substrate.

4. The patterning method of claim 1, wherein the etching process comprises an anisotropic plasma etching process.

5. The patterning method of claim 1, wherein the anisotropic plasma etching process is performed by directing an ionized plasma via a field.

6. The patterning method of claim 5, wherein the ionized plasma is formed by ionizing a plasma source comprising at least one inert gas selected from a group consisting of helium (He), neon (Ne), argon (Ar), krypton (Kr) and xenon (Xe).

7. The patterning method of claim 5, wherein a flow rate of the ionized plasma is in a range of about 20 sccm to about 200 sccm.

8. The patterning method of claim 6, wherein the plasma source further comprises an external plasma source.

9. The patterning method of claim 8, wherein the external plasma source comprises CF₄:CHF₃, CF₄:CH₂F₂, C₂F₆:CHF₃ or C₂F₆:CH₂F₂.

10. The patterning method of claim 9, wherein a gas flow ratio of CF₄ to CHF₃ of the CF₄:CHF₃, a gas flow ratio of CF₄ to CH₂F₂ of the CF₄:CH₂F₂, a gas flow ratio of C₂F₆ to CHF₃ of the C₂F₆:CHF₃, or a gas flow ratio of C₂F₆ to CHF₃ of the C₂F₆:CHF₃ is larger than 1.

11. The patterning method of claim 5, wherein the field comprises an electric field or a magnetic field.

12. The patterning method of claim 11, wherein a power applied at one electrode for generating the electric field is in a range of about 150 W to about 300 W.

13. The patterning method of claim 1, wherein a thickness of the patterned photoresist layer is in a range of about 200 nm to about 500 nm.

14. The patterning method of claim 1, wherein the photoresist layer comprises a positive photoresist layer or a negative photoresist layer.

15. The patterning method of claim 1, wherein the film comprises a single layer or multiple layers.

16. The patterning method of claim 1, wherein the film comprises a dielectric layer, an inter-metal dielectric (IMD) layer or an inter-layer dielectric (ILD) layer.

17. The patterning method of claim 1, wherein the film comprises an oxide layer, a nitride layer, a poly-silicon layer or a single crystal silicon layer.

18. The patterning method of claim 1, wherein the patterning method is performed to form a trench structure, a contact structure or a via structure in the film.

19. The patterning method of claim 17, wherein the trench structure comprises a shallow trench isolation (STI) structure.
